(19) United States
(12) Patent Application Publication
(10) Pub. No.: US 2026/0297270 A1
(43) Pub. Date: Oct. 1, 2026

(54) POLYIMIDE FILM AND METHOD FOR PRODUCING SAME

(71) Applicant: PI ADVANCED MATERIALS CO., LTD., Chungcheongbuk-do (KR)

(72) Inventors: Dae-Geon YOO, Chungcheongbuk-do (KR); Dong-Young KIM, Chungcheongbuk-do (KR); Dong-Young WON, Chungcheongbuk-do (KR)

(21) Appl. No.: 18/996,400

(22) PCT Filed: Jul. 21, 2023
(86) PCT No.: PCT/KR2023/010582

§ 371 Date: Jan. 17, 2025

(30) Foreign Application Priority Data
Jul. 22, 2022 (KR) 10-2022-0091118

(51) Int. Cl. C08J 5/18; C08G 73/10; C23C 14/20; C23C 14/34; C25D 5/56

(52) U.S. Cl. CPC C08J 5/18; C23C 14/20; C23C 14/34; C25D 5/56; C08G 73/1042; C08J 2379/08

(57) ABSTRACT

The present invention provides: a polyimide film having a surface hardness of 0.4 GPa to 0.6 GPa, as measured by a nanoindenter; and a method for producing same.

### TECHNICAL FIELD

The present disclosure relates to a polyimide film that is excellent in both dimensional stability and adhesive strength. More specifically, the present disclosure relates to a polyimide film with high surface hardness and minimal difference in adhesive strength between room temperature adhesive strength and heat-resistant adhesive strength and to a method of preparing the same.

### BACKGROUND ART

Polyimide (PI) has a rigid aromatic main chain. Polyimide (PI) is based on an imide ring with excellent chemical stability. Thereby, polyimide is a polymer material that has the highest level of heat resistance, chemical resistance, electrical insulation, chemical resistance, and weather resistance among organic materials.

A polyimide film is attracting attention as a material for various electronic devices that require the above-mentioned properties.

Examples of microelectronic components to which the polyimide film is applied include a thin, flexible circuit board with high circuit integration to cope with lightweighting and miniaturization of electronic products. The polyimide film is especially widely used as an insulating film for a thin circuit board.

The thin circuit board generally has a structure in which a circuit including a metal foil is formed on an insulating film. In a broad sense, this thin circuit board is referred to as a flexible metal foil clad laminate. When such a thin circuit board uses a thin copper plate as a metal foil, it is also referred to as a flexible copper clad laminate (FCCL) in a narrower sense.

A method of manufacturing a flexible metal foil clad laminate includes, for example, (i) a casting method in which polyamic acid, a precursor of polyimide, is cast or applied onto a metal foil and then imidized, (ii) a metallizing method of installing a metal layer directly on a polyimide film by sputtering, and (iii) a laminate method of bonding a polyimide film and a metal foil through thermoplastic polyimide using heat and pressure.

In particular, the metallizing method is a method of manufacturing a flexible metal foil clad laminate by, for example, sputtering a metal such as copper on a polyimide film with a thickness of 20 to 38 μm and sequentially forming a tie layer and a seed layer by depositing the metal. This method has the advantage of forming an ultrafine circuit with a circuit pattern pitch of 35 μm or less. As a result, this method is widely used to manufacture a flexible metal foil clad laminate for chip on film (COF).

The polyimide film used in the flexible metal foil clad laminate by the metallizing method is required to have high dimensional stability and high adhesive strength to a sputtered metal foil. However, a polyimide film with high dimensional stability usually has the problem of reduced adhesive strength to the sputtered metal foil.

Therefore, there is an urgent need for a polyimide film that has both high dimensional stability and excellent adhesive strength to the sputtered metal foil.

In particular, there is an emerging need to minimize the reduction in adhesive strength to the sputtered metal foil due to dimensional changes in a polyimide film during a sputtering process and subsequent processes.

The information described in the background technique is intended to help understand the background of the present disclosure. It may include matters that are not conventional art already known to those skilled in the art to which this technique pertains.

### RELATED ART DOCUMENT

### Patent Document

(Patent document 1) Korean Patent Application Publication No. 10-2020-0120515

### DISCLOSURE

### Technical Problem

Accordingly, an objective of the present disclosure is to provide a polyimide film that has both high dimensional stability and excellent adhesive strength.

In particular, the objective of the present disclosure is to provide a polyimide film that has excellent surface hardness and minimizes the decrease in adhesive strength to a sputtered metal foil during a sputtering process and subsequent processes.

However, the problem to be solved by the present disclosure is not limited to the problems mentioned above, and other problems not mentioned will be clearly understood by those skilled in the art from the description below.

### Technical Solution

One aspect of the present disclosure to achieve the objective provides
a polyimide film that has a surface hardness of 0.4 to 0.6 GPa, as measured by a nanoindenter.

Another aspect of the present disclosure provides a method of preparing a polyimide film, the method including:
(a) preparing polyamic acid by polymerizing dianhydride components including 3,3′, 4,4′-biphenyltetracarboxylic dianhydride (BPDA) and pyromellitic dianhydride (PMDA) with diamine components including two or more selected from the group consisting of para-phenylene diamine (PPD), oxydianiline (ODA), and 1,3-bis(aminophenoxy)benzene (TPE-R) in an organic solvent; and
(b) imidizing the polyamic acid.

A further aspect of the present disclosure provides a flexible metal foil clad laminate containing the polyimide film and an electrically conductive restraint.

A yet further aspect of the present disclosure provides
an electronic component including the flexible metal foil clad laminate.

### Advantageous Effects

The present disclosure provides a polyimide film in which the composition ratio and reaction ratio of dianhydride and diamine components are adjusted. Thereby, the present disclosure provides a polyimide film which has excellent adhesive strength as well as excellent dimensional stability.

This polyimide film can be applied to various fields which require a polyimide film with excellent dimensional stability and excellent adhesive strength, for example, to a flexible in metal foil clad laminate manufactured by a metallizing method or can be applied to an electronic component including such flexible metal foil clad laminate.

### BEST MODE

Terms or words used in this specification and claims should not be construed as limited to their usual or dictionary meanings. Based on the principle that inventor(s) can appropriately define the concept of the terms to explain his or her invention in the best way, the terms or words should be interpreted with meaning and concept consistent with the technical idea of the present disclosure.

Therefore, the configuration of the embodiments described in this specification is only one of the most preferred embodiments of the present disclosure and does not represent the entire technical idea of the present disclosure. Thus, it should be understood that at the time of filing this application, there may be various equivalents and modifications which can replace them.

In this specification, singular expressions include plural expressions unless the context clearly dictates otherwise. In this specification, terms such as “include”, “comprise”, or “have” are intended to indicate the presence of implemented features, numbers, steps, components, or combinations thereof. It should be understood that these do not preclude the presence or addition of one or more other features, numbers, steps, components, or combinations thereof.

In this specification, “dianhydride” is intended to include its precursors or derivatives. Although the precursors or derivatives may not technically be dianhydrides, the precursors or derivatives will nonetheless react with diamines to form polyamic acids, which may then be converted back into polyimides.

In this specification, “diamine” is intended to include its precursors or derivatives. Although the precursors or derivatives may not technically be diamines, the precursors or derivatives will nonetheless react with dianhydrides to form polyamic acids, which may then be converted back into polyimides.

In this specification, when an amount, concentration, or other value or parameter is given as a range, preferred range, or enumeration of upper and preferred lower values, it should be understood that all ranges formed by any pair of any upper range limit or preferred value and any lower range limit or preferred value are to be specifically disclosed, regardless of whether the ranges are separately disclosed.

When ranges of numerical values are stated herein, unless otherwise stated, the ranges are intended to include the endpoints and all integers and fractions within the ranges. The scope of the present disclosure is not intended to be limited to the specific values recited when defining the scope.

In this specification, “a to b” and “a to b” that indicate numerical ranges, “to” and “~” are defined as ≥a and ≤b.

A polyimide film according to one embodiment of the present disclosure may have a surface hardness of 0.4 to 0.6 GPa, as measured by a nanoindenter.

For example, the hardness of the surface may be 0.45 GPa or more, 0.5 GPa or more, or 0.55 GPa or more.

When the surface hardness exceeds the range, deposition of metal foil becomes difficult and the room temperature adhesive strength of the polyimide film may weaken. When the surface hardness is below the range, the thermal stability and heat-resistant adhesive strength of the polyimide film may be reduced.

In another embodiment, the polyimide film has a room temperature adhesive strength of 0.6 kgf/cm to 0.9 kgf/cm to a metal foil and a heat-resistant adhesive strength of 0.3 kgf/cm to 0.5 kgf/cm to the metal foil.

The room temperature adhesive strength may be an adhesive strength between the polyimide film and the metal foil measured at room temperature (15° C. to 25° C.) after depositing a metal foil (e.g., copper foil) on the polyimide film through a sputtering process.

In addition, the heat-resistant adhesive strength may be an adhesive strength between the polyimide film and the metal foil measured after depositing a metal foil (for example, copper foil) on the polyimide film through a sputtering process and leaving the resulting product at a high temperature (100° C. to 200° C.) for a long time (100-300 hours).

For example, the room temperature adhesive strength may be in a range of 0.6 kgf/cm to 0.83 kgf/cm, and the heat-resistant adhesive strength may be in a range of 0.45 kgf/cm to 0.50 kgf/cm.

When the room temperature and/or heat-resistant adhesive strength exceeds or falls below the range, problems may occur in the production process of products to which the polyimide film is applied.

In a further embodiment, a reduction rate in adhesive strength expressed in Equation 1 below may be 50% or less, and a thermal expansion coefficient may be greater than 1 ppm/° C. and 15 ppm/° C. or less.

$$Reduction rate in adhesive strength ( \% ) = [ ( room temperature adhesive strength to metal foil - heat - resistant adhesive strength to metal foil ) / room temperature adhesive strength to metal foil ] * 100 \qquad [ Equation 1 ]$$

The reduction rate in adhesive strength may be, for example, 45% or less, 40% or less, 35% or less, 30% or less, 25% or less, and 20% or less.

Meanwhile, the thermal expansion coefficient may be, for example, 4.5 ppm/° C. to 10 ppm/° C.

When the thermal expansion coefficient exceeds the range, the heat-resistant stability of the deposited metal foil and polyimide film may be reduced. When the thermal expansion coefficient is below the range, the room temperature adhesive strength between the polyimide film and the metal foil may be reduced.

In a yet further embodiment, the polyimide film of the present disclosure may be obtained by subjecting a polyamic acid solution to an imidization reaction, the polyamic acid solution containing dianhydride components including 3,3′,4,4′-biphenyltetracarboxylic dianhydride (BPDA) and pyromellitic dianhydride (PMDA) and diamine components including two or more selected from the group consisting of para-phenylene diamine (PPD), oxydianiline (ODA), and 1,3-bis(aminophenoxy)benzene (TPE-R).

However, the polyimide film of the present disclosure may not contain 3,3′,4,4′-benzophenone tetracarboxylic dianhydride (BTDA) and 4,4′-oxydiphthalic anhydride (ODPA) as the dianhydride components.

In addition, the polyimide film of the present disclosure may not contain m-tolidine (MTD) as the diamine components.

For example, the diamine component of the polyimide film for use may be a combination of para-phenylene diamine and oxydianiline, or a combination of para-phenylene diamine and 1,3-bis(aminophenoxy)benzene (TPE-R).

The polyimide chain derived from 3,3′,4,4′-biphenyltetracarboxylic dianhydride has a structure named charge transfer complex (CTC). That is, the polyimide chain has a regular straight structure in which the electron donor and electron acceptor are located close to each other. This strengthens intermolecular interactions.

In addition, pyromellitic dianhydride is a dianhydride component with a relatively rigid structure and is preferable because pyromellitic dianhydride may provide appropriate elasticity to the polyimide film.

On the other hand, 3,3′,4,4′-biphenyltetracarboxylic dianhydride contains two benzene rings corresponding to the aromatic portion, meanwhile, pyromellitic dianhydride contains one benzene ring corresponding to the aromatic moiety. The increase in pyromellitic dianhydride content in the dianhydride component may be understood as an increase in the imide group within the molecule based on the same molecular weight. This may be understood as the proportion of imide groups derived from the pyromellitic dianhydride in the polyimide polymer chain increases relative to the imide group derived from 3,3′,4,4′-biphenyltetracarboxylic dianhydride.

In a still yet further embodiment, based on 100 mol % of the total content of the dianhydride components, the 3,3′,4,4′-biphenyltetracarboxylic dianhydride may be contained in an amount of 40 mol % to 99 mol %, and the pyromellitic dianhydride may be contained in an amount of 1 mol % to 60 mol %. Based on 100 mol % of the total content of the diamine components, the para-phenylene diamine may be contained in an amount of 40 mol % to 95 mol %, the oxydianiline may be contained in an amount of 30 mol % or less, and the 1,3-bis(aminophenoxy)benzene may be contained in an amount of 60 mol % or less.

For example, based on 100 mol % of the total content of the dianhydride components, the 3,3′,4,4′-biphenyltetracarboxylic dianhydride may be contained in an amount of 50 mol % to 97 mol %, and the pyromellitic dianhydride may be contained in an amount of 3 mol % to 50 mol %.

In addition, based on 100 mol % of the total content of the diamine components, the para-phenylene diamine may be contained in an amount of 55 mol % to 87 mol %, and the oxydianiline may be contained in an amount of 13 mol % or less, and the 1,3-bis(aminophenoxy)benzene may be contained in an amount of 45 mol % or less.

Among the dianhydride components and diamine components, when the content of short-structured monomers such as the para-phenylene diamine and the pyromellitic dianhydride increases, the surface hardness of the polyimide film may tend to increase and the thermal expansion coefficient of the polyimide film may tend to be reduced.

On the other hand, among the dianhydride components and diamine components, when the content of monomers with a flexible structure such as the oxydianiline and the 3,3′,4,4′-biphenyltetracarboxylic dianhydride increases, the surface hardness of the polyimide film may tend to be reduced and the thermal expansion coefficient of the polyimide film may tend to increase.

In the present disclosure, the preparation of polyamic acid, for example, may include:
(1) a polymerizing method by placing the entire amount of the diamine components in a solvent and then adding the dianhydride components in substantially equimolar amounts to the diamine components;
(2) a polymerizing method by placing the entire amount of the dianhydride components in a solvent and then adding the diamine components in substantially equimolar amounts to the dianhydride components;
(3) a polymerizing method by adding some amount of the diamine components into a solvent and then mixing some amount of the dianhydride components in a ratio of about 95 mols to 105 mol % with respect to the reaction components, and then adding the remaining amount of the diamine components and subsequently adding the remaining amount of the dianhydride components so that the diamine components and the dianhydride components are substantially equimolar;
(4) a polymerizing method by adding a predetermined amount of a dianhydride component into a solvent and then mixing some amount of the diamine components in a ratio of 95 mol % to 105 mol % with respect to the reaction component, and then adding a predetermined amount of another dianhydride component and subsequently adding the remaining amount of the diamine components so that the diamine components and the dianhydride components are substantially equimolar;
(5) a polymerizing method by reacting some amount of the diamine components and some amount of the dianhydride components in a solvent, ensuring that either one of the diamine components and dianhydride components is in excess, thereby forming a first composition and reacting some amount of the diamine components and some amount of the dianhydride components in another solvent, ensuring that either one of the diamine components and dianhydride components is in excess, thereby forming a second composition, and then mixing the first and second compositions and completing polymerization. At this point, when the diamine components are excessive when forming the first composition, the dianhydride components are added in in the second composition, excess meanwhile, when the dianhydride components are excessive in the first composition, the diamine components are excessive in the second composition.

In this way, the first and second compositions may be mixed and polymerized so that the total diamine components and dianhydride components used in these reactions are substantially equimolar.

However, the polymerization methods are not limited to the examples, and of course, any known method may be used to prepare polyamic acid.

In one specific example, the method of preparing a polyimide film according to the present disclosure may include:
(a) preparing polyamic acid by polymerizing dianhydride components including 3,3′,4,4′-biphenyltetracarboxylic dianhydride (BPDA) and pyromellitic dianhydride (PMDA) with diamine components including two or more selected from the group consisting of para-phenylene diamine (PPD), oxydianiline (ODA), and 1,3-bis(aminophenoxy)benzene (TPE-R) in an organic solvent; and
(b) imidizing the polyamic acid.

In a still yet further embodiment, based on 100 mol % of the total content of the dianhydride components, the 3,3′,4,4′-biphenyltetracarboxylic dianhydride may be contained in an amount of 40 mol % to 99 mol %, and the pyromellitic dianhydride may be contained in an amount of 1 mol % to 60 mol %. Based on 100 mol % of the total content of the diamine components, the para-phenylene diamine may be contained in an amount of 40 mol % to 95 mol %, the oxydianiline may be contained in an amount of 30 mol % or less, and the 1,3-bis(aminophenoxy)benzene may be contained in an amount of 60 mol % or less.

Meanwhile, the polyimide film may have a surface hardness of 0.4 Gpa to 0.6 Gpa, as measured by a nanoindenter, adhesive strength of 0.6 kgf/cm to 0.9 kgf/cm to a metal foil at room temperature, and heat-resistant adhesive strength of 0.3 kgf/cm to 0.5 kgf/cm to the metal foil.

In the present disclosure, the polymerization method of polyamic acid as described above may be defined as a random polymerization method. The polyimide film made from the polyamic acid of the present disclosure and prepared through the process may be preferably applied to obtain the effects of the present disclosure of improving mechanical properties, heat resistance, and chemical resistance.

Meanwhile, the solvent for synthesizing polyamic acid is not particularly limited, and any solvent that dissolves polyamic acid may be used, but an amide-based solvent is preferable.

Specifically, the solvent may be an organic polar solvent. Specifically, the solvent may be an aprotic polar solvent. For example, the solvent may include one or more selected from the group consisting of N, N-dimethylformamide (DMF), N,N-dimethylacetamide (DMAC), N-methyl-pyrrolidone (NMP), chlorophenol, o-chlorophenol, N-methyl-pyrrolidone (NMP), gamma butyrolactone (GBL), and diglyme, but is not limited thereto. The solvent may be used individually or in combination of two or more types as needed.

In another example, N, N-dimethylformamide and N, N-dimethylacetamide may be particularly preferably used as the solvent.

In addition, in the polyamic acid preparation process, fillers other than nano silica may be added to improve various properties of the film such as sliding properties, thermal conductivity, corona resistance, and loop hardness. The added fillers are not particularly limited, but preferred examples include titanium oxide, silicon alumina, nitride, boron nitride, calcium hydrogen phosphate, calcium phosphate, and mica.

The particle size of the fillers is not particularly limited and may be determined depending on the film properties to be modified and the type of the fillers to be added. Generally, the average particle diameter of the fillers is 0.05 μm to 100 μm, preferably 0.1 μm to 75 μm, more preferably 0.1 μm to 50 μm, and particularly preferably 0.1 μm to 25 μm.

When the particle size is below this range, it is difficult to achieve a reforming effect, and when the particle size is above this range, the surface properties may be greatly damaged or the mechanical properties may be greatly reduced.

In addition, the amount of added fillers is not particularly limited and may be determined based on the film properties to be modified or the particle size of the fillers. Generally, the amount of added fillers is 0.01 to 100 parts by weight, preferably 0.01 parts by weight to 90 parts by weight, and more preferably 0.02 parts by weight to 80 parts by weight, based on 100 parts by weight of polyimide.

When the amount of added fillers is below this range, it is difficult to achieve a reforming effect due to the fillers, and when it is above this range, the mechanical properties of the film may be significantly damaged. A method of adding the fillers is not particularly limited, and any known method may be used.

In the preparation method of the present disclosure, the polyimide film may be prepared by thermal imidization and chemical imidization.

In addition, the polyimide film may be prepared by a composite imidization method in which thermal imidization and chemical imidization are combined.

The thermal imidization method is a method that excludes use of chemical catalysts and induces the imidization reaction with a heat source such as hot air or an infrared dryer.

The thermal imidization method may induce an amic acid group present in the gel film to be imidized by heat-treating a gel film at a variable temperature in the range of 100° C. to 600° C. Specifically, the gel film may be heat-treated at 200° C. to 500° C., more specifically, 300° C. to 500° C. to imidize the amic acid group present in the gel film.

However, even in the process of forming a gel film, some of the amic acid (about 0.1 to 10 mol %) may be imidized. For this, a polyamic acid composition may be dried at a variable temperature in the range of 50° C. to 200° C., and this may also be included in the scope of the thermal imidization method.

In the case of chemical imidization, a polyimide film may be prepared using a dehydrating agent and an imidizing agent according to methods known in the art. Herein, the term “dehydrating agent” refers to a substance that promotes a ring closure reaction for polyamic acid through dehydrating. Non-limiting examples thereof may include aliphatic acid anhydrides, aromatic acid anhydrides, N,N′-dialkylcarbodiimides, halogenated lower aliphatics, halogenated lower fatty acid anhydrides, aryl phosphonic dihalides, and thionyl halides. Among these, aliphatic acid anhydrides may be preferable from the viewpoint of ease of acquisition and cost. Non-limiting examples thereof may include acetic anhydrides (AA), propionic acid anhydrides, and lactic acid anhydrides, and these may be used alone or in a combination of two or more types.

In addition, the term “imidizing agent” refers to a substance that has the effect of promoting the ring closure reaction for polyamic acid. The imidizing agent may be, for example, an imine-based component such as aliphatic tertiary amines, aromatic tertiary amines, and heterocyclic tertiary amines. Among these, heterocyclic tertiary amines may be preferable from the viewpoint of reactivity as a catalyst. Non-limiting examples of the heterocyclic tertiary amines include quinoline, isoquinoline, β-picoline (BP), and pyridine, and these may be used alone or in a combination of two or more types.

The amount of dehydrating agent added is preferably in the range of 0.5 mole to 5 mole, and particularly preferably in the range of 1.0 mole to 4 mole, based on 1 mole of amic acid groups in the polyamic acid. In addition, the amount of the imidizing agent added is preferably in the range of 0.05 mole to 2 mole, and particularly preferably in the range of 0.2 mole to 1 mole, based on 1 mole of amic acid groups in the polyamic acid.

When the addition amounts of the dehydrating agent and imidizing agent are below the range, chemical imidization may be insufficient, cracks may be formed in the prepared polyimide film, and the mechanical strength of the film may also decrease. In addition, when the addition amounts of the dehydrating agent and imidizing agent exceed the range, imidization may proceed excessively quickly, and in this case, casting may be difficult in a film form or the prepared polyimide film may exhibit brittle characteristics, which is not desirable.

An example of a composite imidization method is to add a dehydrating agent and an imidizing agent to a polyamic acid solution, heat the resulting product at 80° C. to 200° C., preferably 100° C. to 180° C., partially cure and dry the resulting product, and then heat the resulting product at 200° C. to 400° C. for 5 to 400 seconds, thereby, preparing a polyimide film.

The present disclosure provides a flexible metal foil clad laminate containing the above-described polyimide film and an electrically conductive metal foil.

There is no particular limitation on the metal foil used, but for example, when using a multilayer film of the present disclosure for electronic or electrical devices, the metal foil may be a metal foil containing copper or its alloy, stainless steel or its alloy, nickel or its alloy (also includes 42 alloy), aluminum or its alloy.

In general flexible metal foil clad laminates, copper foils such as rolled copper foil and electrolytic copper foil are widely used, and may also be preferably used in the present disclosure. In addition, a rust-prevention layer, a heat-resistant layer, or an adhesive layer may be applied to the surface of these metal foils.

In the present disclosure, the thickness of the metal foil is not particularly limited, and any thickness is sufficient on the condition that the metal foil with the thickness may function depending on the intended use.

The flexible metal foil clad laminate according to the present disclosure may have a structure in which a metal foil is deposited on one side of the polyimide film. Alternatively, the flexible metal foil clad laminate according to the present disclosure may have a structure in which an adhesive layer containing thermoplastic polyimide is added to one side of the polyimide film, and the metal foil is deposited while attached to the adhesive layer.

The present disclosure also provides an electronic component including the flexible metal foil clad laminate as an electrical signal transmission circuit.

### MODE FOR DISCLOSURE

Hereinafter, the operation and effects of the present disclosure will be described in more detail through specific examples of the present disclosure. However, these examples are merely presented as examples of the present disclosure, and the scope of the present disclosure is not determined by the examples.

### Preparation Example 1: Preparation of Polyimide Film

Nitrogen was injected into a 500 ml reactor equipped with a stirrer and nitrogen injection/discharge pipes as DMF was added, and the temperature of the reactor was set to 30° C. Then, as diamine components, some of para-phenylene diamine (PPD), m-tolidine (MTD), 1,3-bis(aminophenoxy)benzene (TPE-R), and oxydianiline (ODA) were selected and added, and as dianhydride some components, of 3,3′,4,4′-biphenyltetracarboxylic dianhydride (BPDA), pyromellitic dianhydride (PMDA), and oxydiphthalic anhydride (ODPA) were selected and added. Thereafter, it was confirmed that the added components were completely dissolved.

Next, the temperature of the reactor was raised to 40° C. under a nitrogen atmosphere, and stirring was continued for 120 minutes while heating to prepare a polyamic acid solution.

A precursor composition for a polyimide film was obtained by adding 3 moles of acetic anhydride and 1 mole of isoquinoline per mole of an amic acid group to the polyamic acid solution prepared in this way.

The precursor composition for polyimide film was cast on a SUS plate using a doctor blade and dried at 110° C. for 4 minutes to prepare a gel film.

After separating the gel film from the SUS plate, the gel film was heat treated at 380° C. for 8 minutes to prepare a polyimide film with a thickness of 35 μm.

The thickness of the prepared polyimide film was measured using Anritsu's electric film thickness tester.

### Examples 1 to 3 and Comparative Examples 1 to 4

The preparation for polyimide film was carried out according to the preparation example described above, but the contents of diamine monomer and dianhydride monomer were adjusted as shown in Table 1.

TABLE 1

| | Dianhydride | | | Diamine | | | |
|---|---|---|---|---|---|---|---|
| | (mole %) | | | (mole %) | | | |
| | PMDA | BPDA | ODPA | ODA | TPE-R | MTD | PPD |
| Example 1 | 25 | 75 | — | — | 45 | — | 55 |
| Example 2 | 3 | 97 | — | — | 45 | — | 55 |
| Example 3 | 50 | 50 | — | 13 | — | — | 87 |
| Comparative | 50 | 50 | — | — | — | 40 | 60 |
| Example 1 | | | | | | | |
| Comparative | 50 | 50 | — | 100 | — | — | — |
| Example 2 | | | | | | | |
| Comparative | 25 | 75 | — | 55 | 45 | — | — |
| Example 3 | | | | | | | |
| Comparative | 25 | 50 | 25 | 55 | 45 | — | — |
| Example 4 | | | | | | | |

### Preparation Example 2: Preparation of Flexible Metal Foil Clad Laminate

A copper thin layer with a thickness of film approximately 80 nm to 300 nm was deposited as a copper seed layer for electroplating electrodes through sputtering on the polyimide films of Examples 1 to 3 and Comparative Examples 1 to 4, which were prepared according to Preparation Example 1. Then, a copper conductive layer for each Example with a thickness of approximately 8 μm to 9 μm was formed through electroplating.

### (1) Measurement of Thermal Expansion Coefficient

The coefficient of thermal expansion (CTE) was measured using TA's thermomechanical analyzer Q400 model. The polyimide films of Examples 1 to 3 and Comparative Examples 1 to 4, which were prepared by Preparation Example 1, were cut into pieces of 4 mm in width and 20 mm in length. Thereafter, the film pieces were subjected to a tension of 0.05 N under a nitrogen atmosphere. With that, the temperature was raised from 30° C. to 400° C. at a rate of 10° C./min and then cooled again at a rate of 10° C./min. A slope of the 50° C. to 200° C. section (the rate of change in dimensions depending on the temperature change in the 50° C. to 200° C. section (ppm/° C.)) was measured.

### (2) Surface Hardness Measurement

After cutting the polyimide films of Examples 1 to 3 and Comparative Examples 1 to 4, which were prepared by Preparation Example 1, into 100 mm in width and 100 mm in length, force applied to a probe while press-fitting the probe into the each of the samples was measured using KLA-Tenco's iNano Nanoindentor which measures surface hardness. Thereby surface hardness was measured.

### (3) Room Temperature Adhesive Strength Measurement

The flexible metal foil clad laminates manufactured according to Preparation Example 2 using the polyimide films of Examples 1 to 3 and Comparative Examples 1 to 4 were etched into a 2 mm wide rod shape using a wet etching method. Then, the wet-etched flexible metal foil clad laminates were pulled at a speed of 20 mm/min in a 90° peel test using a Universal Testing Machine to measure room temperature adhesive strength.

The wet etching method was carried out by attaching 2 mm wide rod-shaped coating films to the flexible metal foil clad laminates, metal etching by spraying an etchant (ferric chloride [iron III]) to form a rod-shaped pattern and then removing the coating films.

### (4) Heat-Resistant Adhesive Strength Measurement

The flexible metal foil clad laminates manufactured according to Preparation Example 2 using the polyimide films of Examples 1 to 3 and Comparative Examples 1 to 4 were etched into a 2 mm wide rod shape using a wet etching method. Then, the wet-etched flexible metal foil clad laminates were heat treated at 150° C. for 168 hours.

The wet etching method was performed in the same manner as in the room temperature adhesive strength measurement.

Afterward, room temperature adhesive strength was measured by pulling the flexible metal foil clad laminates at a speed of 20 mm/min through a 90° peel test using a Universal Testing Machine.

The coefficient of thermal expansion (CTE), surface hardness, room temperature adhesive strength, and heat-resistant adhesive strength of the polyimide films of Examples 1 to 3 and Comparative Examples 1 to 4, which were prepared by Preparation Example 1, measured using the above-described measurement methods are shown in Table 2 below.

In addition, the reduction: in adhesive strength calculated by Equation 1 above is shown in Table 2 below.

TABLE 2

| | | | Room | Heat- | |
|---|---|---|---|---|---|
| | | | temperature | resistant | Reduction |
| | | Surface | adhesive | adhesive | in adhesive |
| | CTE | hardness | strength | strength | strength |
| | (ppm/° C.) | (GPa) | (kgf/cm) | (kgf/cm) | (%) |
| Example 1 | 10.0 | 0.48 | 0.60 | 0.50 | 17 |
| Example 2 | 8.6 | 0.51 | 0.83 | 0.45 | 46 |
| Example 3 | 4.5 | 0.55 | 0.73 | 0.45 | 33 |
| Comparative | 1.0 | 0.69 | 0.57 | 0.53 | 36 |
| Example 1 | | | | | |
| Comparative | 33.5 | 0.33 | 0.92 | 0.28 | 70 |
| Example 2 | | | | | |
| Comparative | 34.5 | 0.39 | 1.01 | 0.24 | 76 |
| Example 3 | | | | | |
| Comparative | 37.1 | 0.38 | 0.93 | 0.27 | 71 |
| Example 4 | | | | | |

As a result of measurements, the polyimide films of Examples 1 to 3 showed thermal expansion coefficient of greater than 1 ppm/° C. and 15 ppm/° C. or less, surface hardness of 0.4 Gpa to 0.6 Gpa, room temperature adhesive strength of 0.6 to 0.9 kgf/cm, heat-resistant adhesive strength of 0.3 kgf/cm to 0.5 kgf/cm, and reduction in adhesive strength of 50% or less.

In contrast, the polyimide films of Comparative Examples 1 to 4 did not satisfy the characteristic ranges of the polyimide films of the present disclosure in one or more of the following characteristics: thermal expansion coefficient, surface hardness, room temperature adhesive strength, heat resistance adhesive strength, and reduction in adhesive strength.

Therefore, the multilayer polyimide films of Examples 1 to 3 prepared within the appropriate ranges of the present disclosure were excellent in all thermal dimensional stability, dimensional stability against moisture, and adhesive strength to copper foil. However, it was confirmed that when the preparation was made outside the appropriate ranges of the present disclosure, it was difficult to satisfy all of the thermal dimensional stability, dimensional stability against moisture, and adhesive strength to a copper foil of the multilayer polyimide films of the present disclosure.

In other words, it was confirmed that multilayer polyimide films which had excellent dimensional stability and adhesive strength to copper foil and satisfied all of the various conditions applicable to application fields were polyimide films prepared within the appropriate ranges of the present disclosure.

The examples of the polyimide films and the method of preparing the polyimide films of the present disclosure are only preferred examples, which allow those skilled in the art to implement the present disclosure easily, and the examples are not limited to the above-mentioned examples. Since the present disclosure is not limited to the examples, the scope of the present disclosure is not limited thereby. Therefore, the true technical protection scope of the present disclosure should be determined by the technical spirit of the attached patent claims. In addition, it will be clear to those skilled in the art that various substitutions, modifications, and changes can be made without departing from the technical spirit of the present disclosure, and it is obvious that parts that can be easily changed by those skilled in the art are also included in the scope of rights of the present disclosure.

### INDUSTRIAL APPLICABILITY

The present disclosure provides a polyimide film in which the composition ratio and reaction ratio of dianhydride and diamine components are adjusted. Thereby, the present disclosure provides a polyimide film which has excellent adhesive strength as well as excellent dimensional stability.

This polyimide film can be applied to various fields which require a polyimide film with excellent dimensional stability and excellent adhesive strength, for example, to a flexible metal foil clad laminate manufactured by a metallizing method or an electronic component including such flexible metal foil clad laminate.

1. A polyimide film, which has a surface hardness of 0.4 GPa to 0.6 GPa, as measured by a nanoindenter.

2. The polyimide film of claim 1, wherein the polyimide film has a room temperature adhesive strength of 0.6 kgf/cm to 0.9 kgf/cm to a metal foil and a heat-resistant adhesive strength of 0.3 kgf/cm to 0.5 kgf/cm to the metal foil.

3. The polyimide film of claim 1, wherein a reduction rate in adhesive strength expressed in Equation 1 below is 50% or less, and
a thermal expansion coefficient is greater than 1 ppm/° C. and 15 ppm/° C. or less.
$$Reduction rate in adhesive strength ( \% ) = [ ( room temperature adhesive strength to metal foil - heat - resistant adhesive strength to metal foil ) / room temperature adhesive strength to metal foil ] * 100 \qquad [ Equation 1 ]$$

4. The polyimide film of claim 1, wherein the polyimide film is obtained by subjecting a polyamic acid solution to an imidization reaction, the polyamic acid solution containing dianhydride components comprising 3,3′,4,4′-biphenyltetracarboxylic dianhydride (BPDA) and pyromellitic dianhydride (PMDA), and diamine components comprising two or more selected from the group consisting of para-phenylene diamine (PPD), oxydianiline (ODA), and 1,3-bis(aminophenoxy)benzene (TPE-R).

5. The polyimide film of claim 4, wherein, based on 100 mol % of the total content of the dianhydride components, the 3,3′,4,4′-biphenyltetracarboxylic dianhydride is contained in an amount of 40 mol % to 99 mol %, and the pyromellitic dianhydride is contained in an amount of 1 mol % to 60 mol %, and
based on 100 mol % of the total content of the diamine components, the para-phenylene diamine is contained in an amount of 40 mol % to 95 mol %, the oxydianiline is contained in an amount of 30 mol % or less, and the 1,3-bis(aminophenoxy)benzene is contained in an amount of 60 mol % or less.

6. A method of preparing a polyimide film, the method comprising:
(a) preparing polyamic acid by polymerizing dianhydride components comprising 3,3′,4,4′-biphenyltetracarboxylic dianhydride (BPDA) and pyromellitic dianhydride (PMDA) with diamine components comprising two or more selected from the group consisting of para-phenylene diamine (PPD), oxydianiline (ODA), and 1,3-bis(aminophenoxy)benzene (TPE-R) in an organic solvent; and
(b) imidizing the polyamic acid.

7. The method of claim 6, wherein, based on 100 mol % of the total content of the dianhydride components, the 3,3′,4,4′-biphenyltetracarboxylic dianhydride is contained in an amount of 40 mol % to 99 mol %, and the pyromellitic dianhydride is contained in an amount of 1 mol % to 60 mol %, and
based on 100 mol % of the total content of the diamine components, the para-phenylene diamine is contained in an amount of 40 mol % to 95 mol %, the oxydianiline is contained in an amount of 30 mol % or less, and the 1,3-bis(aminophenoxy)benzene is contained in an amount of 60 mol % or less.

8. The method of claim 6, wherein the polyimide film has a surface hardness of 0.4 Gpa to 0.6 Gpa, as measured by a nanoindenter, adhesive strength of 0.6 kgf/cm to 0.9 kgf/cm to a metal foil at room temperature, and heat-resistant adhesive strength of 0.3 kgf/cm to 0.5 kgf/cm to the metal foil.

9. The method of claim 6, wherein a reduction rate in adhesive strength expressed in Equation 1 below is 50% or less, and
a thermal expansion coefficient is greater than 1 ppm/° C. and 15 ppm/° C. or less.
$$Reduction rate in adhesive strength ( \% ) = [ ( room temperature adhesive strength to metal foil - heat - resistant adhesive strength to metal foil ) / room temperature adhesive strength to metal foil ] * 100 \qquad [ Equation 1 ]$$

10. A flexible metal foil clad laminate comprising the polyimide film according to claim 1 and an electrically conductive metal foil.

11. (canceled)
